(19) United States
(12) Patent Application Publication
(10) Pub. No.: US 2021/0203322 A1
(43) Pub. Date: Jul. 1, 2021

(54) OPTIMIZED GATE AND/OR BODY BIAS NETWORK OF A RF SWITCH FET

(71) Applicant: SKYWORKS SOLUTIONS, INC., Irvine, CA (US)

(72) Inventor: Guillaume Alexandre Blin, Carlisle, MA (US)

(21) Appl. No.: 17/122,166

(22) Filed: Dec. 15, 2020

Related U.S. Application Data
(60) Provisional application No. 62/955,761, filed on Dec. 31, 2019.

(51) Int. Cl. H03K 17/687; H03K 17/06

(52) U.S. Cl. CPC H03K 17/6871; H03K 2017/066; H03K 17/063

(57) ABSTRACT

A radio frequency signal switch assembly including a signal input and a signal output, a first control input configured to receive a control signal, a first switch including a first plurality of transistors coupled between the signal input and the signal output, each transistor of the first plurality of transistors having a gate, a drain, and a source, a first common resistor coupled between the first control input and the gate of one transistor of the first plurality of transistors, and a first plurality of gate resistors coupled between the gates of the first plurality of transistors, each gate resistor being coupled between the gates of two adjacent transistors.

### CROSS-REFERENCE TO RELATED APPLICATIONS

This application claims priority under 35 U.S.C. § 119(e) to U.S. Provisional Patent Application Ser. No. 62/955,761, titled OPTIMIZED GATE AND/OR BODY BIAS NETWORK OF A RF SWITCH FET, filed Dec. 31, 2019, which is incorporated herein by reference for all purposes.

### BACKGROUND

Wireless communication devices commonly use one or more instances of transmit and receive circuitry to generate and amplify transmit signals and to amplify and process receive signals, respectively. One or more antennas in such wireless communication devices are typically connected to transmit and receive circuitry through one or more radio-frequency (RF) switches, sometimes referred to as “transmit/receive switches” or “antenna switches.” In addition, RF switches may be included in antenna tuning circuitry connected to the one or more antennas and operated to tune the one or more antennas to different frequencies or frequency bands. During operation, such RF switches must be capable of meeting stringent performance requirements such as insertion loss.

### SUMMARY OF THE INVENTION

At least one aspect of the present disclosure is directed to a radio frequency signal switch assembly including a signal input and a signal output, a first control input configured to receive a control signal, a first switch including a first plurality of transistors coupled between the signal input and the signal output, each transistor of the first plurality of transistors having a gate, a drain, and a source, a first common resistor coupled between the first control input and the gate of one transistor of the first plurality of transistors, and a first plurality of gate resistors coupled between the gates of the first plurality of transistors, each gate resistor being coupled between the gates of two adjacent transistors.

In one embodiment, the first common resistor is coupled to the gate of the transistor disposed closest to the center of the first plurality of transistors. In some embodiments, an off resistance of the first switch corresponds, at least in part, to a series combination of the first plurality of gate resistors. In certain embodiments, each transistor of the first plurality of transistors has a body contact and the switch assembly includes a body control node, a common body resistor coupled between the body control node and the body contact of one transistor of the first plurality of transistors, and a plurality of body resistors coupled between the body contacts of the first plurality of transistors, each body resistor being coupled between the body contacts of two adjacent transistors. In various embodiments, the common body resistor is coupled to the body of the transistor disposed closest to the center of the first plurality of transistors.

In some embodiments, the switch assembly includes a reference node and a second control node, the reference node configured to be coupled to a reference voltage. In one embodiment, the switch assembly includes a second switch including a second plurality of transistors coupled between the reference node and one of the signal input and the signal output, each transistor of the second plurality of transistors having a gate, a drain, and a source. In various embodiments, the switch assembly includes a second plurality of gate resistors coupled between the gates of the second plurality of transistors, each gate resistor being coupled between the gates of two adjacent transistors. In certain embodiments, the switch assembly includes a second common resistor coupled between the second control node and the gate of the transistor of the second plurality of transistors disposed closest to the reference node.

Another aspect of the present disclosure is directed to a switch for a radio frequency signal switch assembly. The switch includes a first node coupled to one of an input and an output of the switch assembly and a second node coupled to a reference voltage, a control node, a plurality of transistors coupled between the first and second nodes, each transistor of the plurality of transistors having a gate, a drain, and a source, a common resistor coupled between the control node and the gate of one transistor of the plurality of transistors, and a plurality of gate resistors coupled between the gates of the plurality of transistors, each gate resistor being coupled between the gates of two adjacent transistors.

In one embodiment, the common resistor is coupled to the gate of the transistor disposed closest to the second node. In some embodiments, an off resistance of the switch corresponds, at least in part, to a series combination of the plurality of gate resistors. In various embodiments, each transistor of the plurality of transistors has a body contact and the switch includes a body control node, a common body resistor coupled between the body control node and the body contact of one transistor of the plurality of transistors, and a plurality of body resistors coupled between the body contacts of the plurality of transistors, each body resistor being coupled between the body contacts of two adjacent transistors. In certain embodiments, the common body resistor is coupled to the body of the transistor disposed closest to the second node.

Another aspect of the present disclosure is directed to a method of designing a switch for a radio frequency signal switch assembly. The method includes arranging a plurality of transistors between a first node and a second node, each transistor of the plurality of transistors having a gate, a drain, and a source, selecting a common resistor to be coupled between a control node and the gate of one transistor of the plurality of transistors, and selecting a plurality of gate resistors to be coupled between the gates of the plurality of transistors, each gate resistor being coupled between the gates of two adjacent transistors.

In one embodiment, the first node is configured to be coupled to an input of the switch assembly and the second node is configured to be coupled to an output of the switch assembly. In various embodiments, the method includes coupling the common resistor to the gate of the transistor disposed closest to the center of the plurality of transistors.

In some embodiments, the first node is configured to be coupled to one of an input and an output of the switch assembly and the second node is configured to be coupled to a reference voltage. In certain embodiments, the method inlcudes coupling the common resistor to the gate of the transistor disposed closest to the second node.

In various embodiments, selecting the plurality of gate resistors includes selecting the plurality of gate resistors to provide a desired off resistance of the switch, the off resistance of the switch corresponding, at least in part, to a series combination of the plurality of gate resistors.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures may be represented by a like numeral. For purposes of clarity, not every component may be labeled in every figure. In the figures:

FIG. 1A is a schematic diagram of an example of a transistor-based switch assembly;

FIG. 1B is a schematic diagram of an example of a transistor-based switch assembly;

FIG. 1C is a schematic diagram of an example of a transistor-based switch assembly;

FIG. 2A is a schematic diagram of a transistor-based switch in accordance with one embodiment;

FIG. 2B is a schematic diagram of a transistor-based switch in accordance with one embodiment;

FIG. 2C is a diagram of a transistor-based switch layout in accordance with one embodiment;

FIG. 2D is a schematic diagram of a transistor-based switch in accordance with one embodiment;

FIG. 3A is a schematic diagram of a transistor-based switch in accordance with one embodiment;

FIG. 3B is a schematic diagram of a transistor-based switch in accordance with one embodiment;

FIG. 3C is a diagram of a transistor-based switch layout in accordance with one embodiment;

FIG. 3D is a schematic diagram of a transistor-based switch in accordance with one embodiment; and

FIG. 4 is a graph illustrating simulated performance characteristics for examples of transistor-based signal switches in accordance with one embodiment.

### DETAILED DESCRIPTION

Aspects and examples are directed to RF switch assemblies and components thereof, and to devices, modules, and systems incorporating the same.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, end, side, vertical and horizontal, and the like, are intended for convenience of description, not to limit the present systems and methods or their components to any one positional or spatial orientation.

As discussed above, wireless communication devices often include one or more RF switches to couple transmit and receive circuity to one or more antennas, and/or to couple the one or more antennas to antenna tuning circuitry. For example, RF switches may be configured to provide transmit signals from transmit circuitry to an antenna, to provide signals received by an antenna to receive circuitry, or to couple an antenna to antenna tuning circuitry. In some examples, the RF switches may be included within antenna tuning circuitry and may be configured to connect and disconnect various combinations of capacitors and inductors to the antenna for tuning purposes. In some examples, such RF switches may be transistor-based switches. In certain examples, such RF switches may include multiple transistor-based switches and the transistor-based switches may be assembled or arranged to provide an RF switch having a desired number of inputs (e.g., poles) and outputs (e.g., throws).

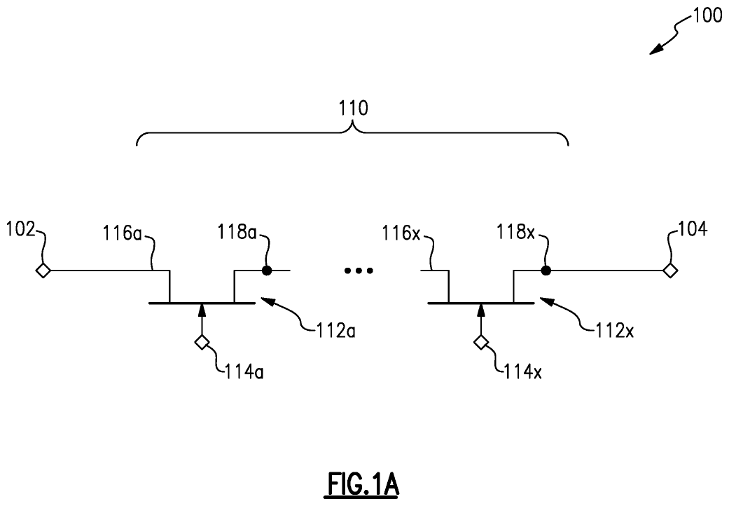

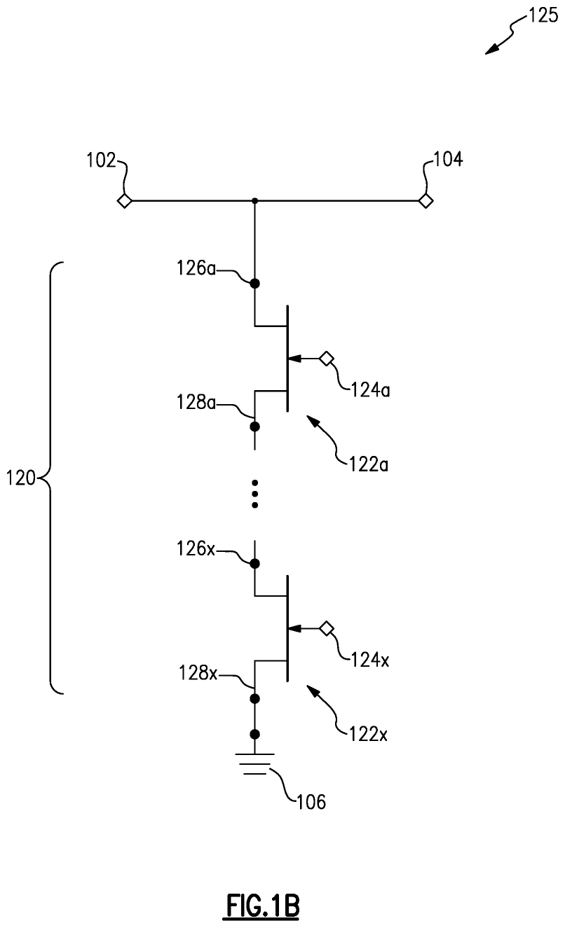

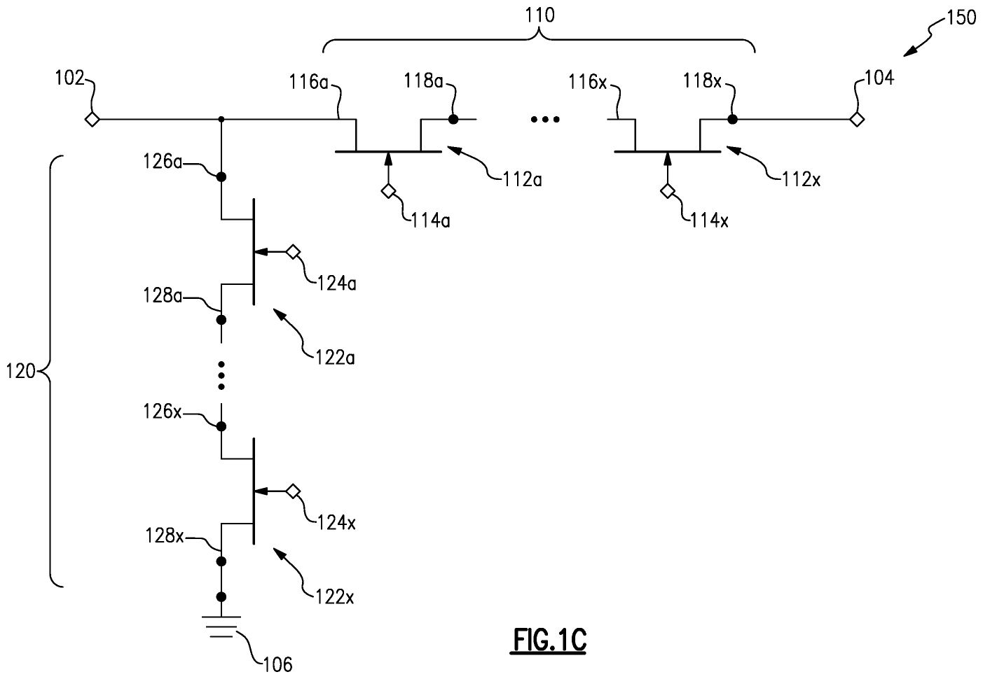

FIG. 1A illustrates one example of a transistor-based signal switch assembly 100 having a signal input 102 and a signal output 104 and including a series switch 110 coupled between the signal input 102 and the signal output 104. In various examples, the signal input 102 and the signal output 104 may be reversible without affecting the component, e.g., the switch 100.

In one example, the series switch 110 includes a plurality of series FETs 112 coupled between the signal input 102 and the signal output 104. Each FET of the plurality of series FETs 112 may have a gate 114, a drain 116, and a source 118. In certain examples, each FET may also have a body contact (not shown). In some examples, the plurality of series FETs 112 includes a first FET 112a having a drain 116a coupled to the signal input 102 and a last FET 112x having a source 118x coupled to the signal output 104. In other examples, the plurality of series FETs 112 may be arranged differently, for example, the source 118a of the first FET 112a may be coupled to the signal input 102 and the drain 116x of the last FET 112x may be coupled to the signal output 104. In some examples, the plurality of series FETs 112 may include additional FETs coupled in series between the first FET 112a and the last FET 112x.

In one example, a control voltage applied to, and received at, the gate 114 of each FET of the plurality of series FETs 112 controls the conductivity of a channel between the drain 116 and the source 118 of each FET. In some examples, the gates 114 of the plurality of series FETs 112 may be coupled to one another and configured to receive the same control voltage, such that the plurality of series FETs 112 may be controlled in unison. In one example, the switch 100 may be operated in an “on state” by controlling the plurality of series FETs 112 to be conducting (on) and in the “off state” by controlling the plurality of series FETs 112 to be non-conducting (off).

FIG. 1B illustrates one example of a transistor-based signal switch assembly 125 including a shunt switch 120 coupled between the signal input 102, the signal output 104, and a reference node 106 (e.g., ground or neutral). In various examples, the signal input 102 and the signal output 104 may be reversible without affecting the component, e.g., the switch 125. In one example, the signal input 102 and/or the signal output 104 of the switch assembly 125 may be coupled to a series switch (e.g., series switch 110 of FIG. 1A). As such, the shunt switch 120 may be configured to shunt signals received at the signal input 102 and/or output 104 when the series switch is non-conducting (off). In some examples, the signal input 102 and/or output 104 of the switch assembly 125 may be coupled to a device (e.g., an amplifier), and the shunt switch 120 may be configured to shunt signals at the input or the output of the device.

In one example, the shunt switch 120 includes a plurality of shunt FETs 122, and each FET of the plurality of shunt FETs 122 has a gate 124, a drain 126, and a source 128. In certain examples, each FET may also have a body contact (not shown). In some examples, the plurality of shunt FETs 122 includes a first FET 122a having a drain 126a coupled to the signal input 102 and signal output 104, and a last FET 122x having a source 128x coupled to the reference node 106. In other examples, the shunt FETs 122 may be arranged differently, for example, the source 128a of the first FET 122a may be coupled to the signal input 102 and the signal output 104, and the drain 126x of the last FET 122x may be coupled to the reference node 106. In some examples, the plurality of shunt FETs 122 may include additional FETs coupled between the first FET 122a and the last FET 122x. For example, the source 128a of the input FET 122a may be coupled to a drain 126b of a second FET 122b, the source 128b of the second FET 122b may be coupled to the drain 126c of a third FET 122c, and so on.

In one example, a control voltage applied to, and received at, the gate 124 of each FET of the plurality of shunt FETs 122 controls the conductivity of a channel between the source 128 and the drain 126 of each FET. In some examples, the gates 124 of the plurality of shunt FETs 122 may be coupled to one another and configured to receive the same control voltage, such that the plurality of shunt FETs 122 may be controlled in unison. In one example, the switch 125 may be operated in an “on state” by controlling the plurality of shunt FETs 122 to be conducting (on) and in the “off state” by controlling the plurality of shunt FETs 122 to be non-conducting (off).

FIG. 1C illustrates one example of a transistor-based signal switch assembly 150 including the series switch 110 between the signal input 102 and the signal output 104 and the shunt switch 120 between the signal input 102 and the reference node 106. In other examples, the shunt switch 120 may be included between the signal output 104 and reference node 106. In various examples, the signal input 102 and the signal output 104 may be reversible without affecting the component, e.g., the switch 150.

The switch 150 is controllable to be in an “on state” to conduct a signal received at the signal input 102 and provide the signal to the signal output 104 by controlling the plurality of series FETs 112 to be conducting (on) and controlling the plurality of shunt FETs 122 to be non-conducting (off) by applying appropriate control voltages to each of the gates 114, 124. Likewise, the switch 150 is controllable to be in an “off state” to substantially block signals received at the signal input 102 by controlling the plurality of series FETs 112 to be non-conducting (off) and controlling the plurality of shunt FETs 122 to be conducting (on) by applying appropriate control voltages to each of the gates 114, 124. In such an off state, the switch 150 prevents signals from passing through to the signal output 104, at least in part due to the plurality of series FETs 112 presenting a (capacitive) open circuit between the input 102 and the output 104, and the plurality of shunt FETs 122 providing a conducting signal path to the reference node 106, substantially diverting the signal received at the signal input 102.

The FETs of the plurality of series FETs 112 and the plurality of shunt FETs 122 in the examples described above may each be one of many types of FETs known in the art. For example, each may be a junction FET (JFET), a metal oxide semiconductor FET (MOSFET), or a silicon on insulator (SOI) MOSFET, and may be of N-channel or P-channel types, and enhancement or depletion mode types. In other examples, each FET may be a gallium arsenide (GaAs) FET, a gallium nitride (GaN) FET, or another type of FET.

As discussed above, the gates 114 of the plurality of series FETs 112 may be coupled together such that the plurality of series FETs 112 may be controlled (e.g., turned on and off) in unison. Similarly, the gates 124 of the plurality of shunt FETs 122 may be coupled together such that the plurality of shunt FETs 122 may be controlled (e.g., turned on and off) in unison. In some examples, control voltages may be applied to the gates 114, 124 through one or more gate resistors.

In many RF applications, it is desirable for transistor-based signal switches to have low insertion loss and a high off resistance (R_{off}). In one example, the insertion loss of a series switch (e.g., switch 110) may correspond to the power loss of a signal provided from the input to the output, or from the output to the input, while the switch is turned on (i.e., closed). Similarly, a series switch (e.g., switch 110) may be arranged with a shunt switch (e.g., switch 120), and the insertion loss of the switch arrangement may correspond to the power loss of a signal provided from the input to the output, or from the output to the input, while the series switch is turned on (i.e., closed) and the shunt switch is turned off (i.e., open). In some examples, the R_{off} of a switch may correspond to the total resistance seen by an RF signal applied to the input (or output) of the switch while the switch is turned off (i.e. open).

As described above, transistor-based signal switches may include gate resistors, and in some examples, the values of the gate resistors can affect the value of R_{off}. For example, the R_{off} of a switch may be proportional to the values of the gate resistors; i.e., higher valued gate resistors may contribute to a higher R_{off} and lower valued gate resistors may contribute to a lower R_{off}. In some examples, the gate resistors may be configured in a parallel arrangement between the gates of each FET and a gate control input and may dissipate power in parallel while the switch (e.g., switch 110) is turned on. As such, increasing the values of the gate resistors may help minimize power dissipation while the switch is turned on (i.e., insertion loss). However, large valued gate resistors may experience poor broadband performance (e.g., high frequency roll-off) and degrade the overall performance of the switch.

An improved transistor-based signal switch is provided herein. In at least one embodiment, the transistor-based signal switch may have an optimized bias network for reducing insertion loss and improving R_{off} over a broadband performance range. In some examples, the optimized bias network may also increase the power handling capability of the switch and reduce the switch footprint.

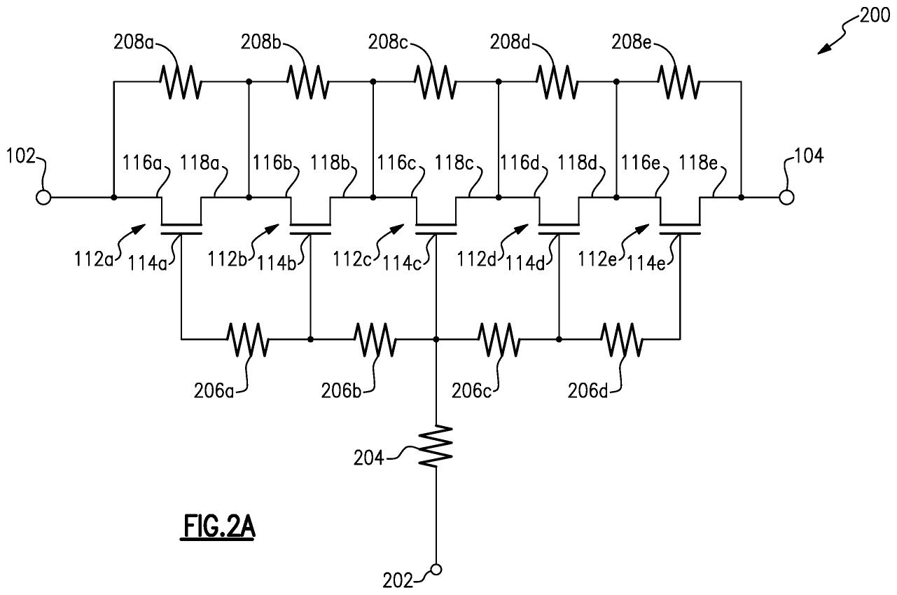

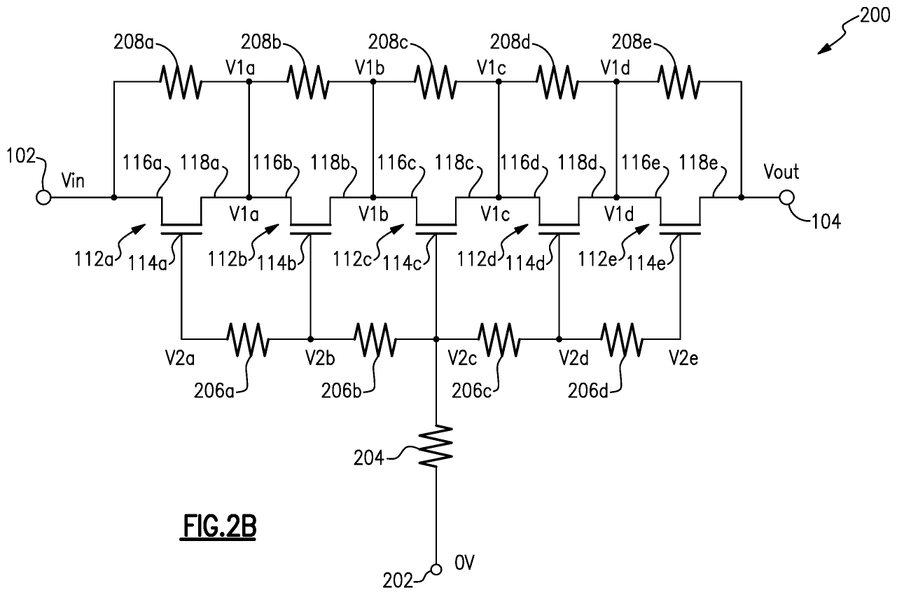

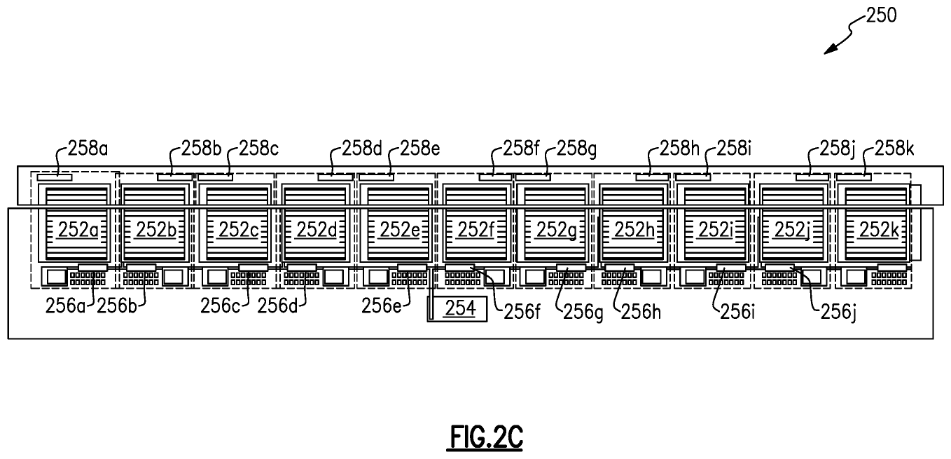

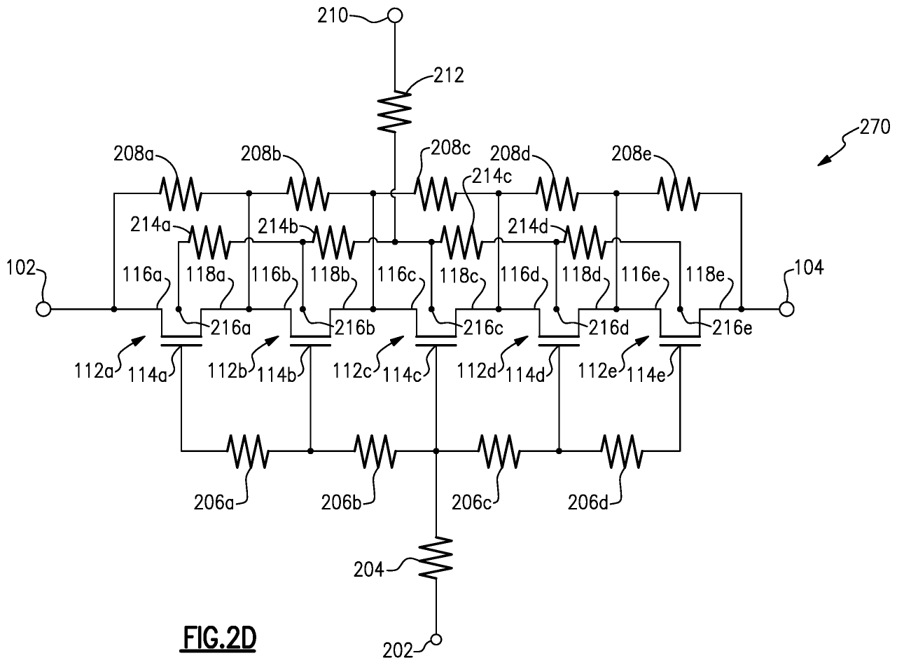

FIG. 2A illustrates one example of a transistor-based signal switch 200. In one example, the switch 200 may be substantially similar to the series switch 110 of FIGS. 1A and 1C, except that the switch 200 includes a gate control input 202 and a common resistor 204 coupled between the gate control input 202 and a plurality of gate-to-gate resistors 206. In some examples, the switch 200 may include a plurality of drain-source resistors 208.

In one example, the plurality of FETs 112 of the switch 200 includes a first FET 112a, a second FET 112b, a third FET 112c, a fourth FET 112d, and a fifth FET 112e coupled between the signal input 102 and the signal output 104. In other examples, the plurality of FETs 112 may include a different number of FETs. As shown in FIG. 2A, a first gate-to-gate resistor 206a may be coupled between the gate 114a of the first FET 112a and the gate 114b of the second FET 112b and a second gate-to-gate resistor 206b may be coupled between the gate 114b of the second FET 112b and the gate 114c of the third FET 112c. Likewise, a third gate-to-gate resistor 206c may be coupled between the gate 114c of the third FET 112c and the gate 114d of the fourth FET 112d and a fourth gate-to-gate resistor 206d may be coupled between the gate 114d of the fourth FET 112d and the gate 114e of the fifth FET 112e.

In some examples, the switch 200 may include the plurality of drain-source resistors 208 coupled in parallel with the plurality of FETs 112 (i.e., each respective drain-source resistor 208 being coupled between the source and drain of a respective FET 112). For example, a first drain-source resistor 208a may be coupled in parallel with the first FET 112a, a second drain-source resistor 208b may be coupled in parallel with the second FET 112b, and so on. In one example, each resistor of the plurality of drain-source resistors 208 may have substantially the same value; however, in other examples, at least one of the resistors may have a different value.

As described above, the plurality of FETs 112 may be coupled between the signal input 102 and the signal output 104, and the signal input 102 and the signal output 104 may be reversible; i.e., the switch 200 may be configured to receive an RF signal at both the signal input 102 and the signal output 104. As such, the common resistor 204 may be coupled between the gate control input 202 and the gate 114 of the FET positioned substantially in the center of the plurality of FETs 112. For example, the common resistor 204 may be coupled between the gate control input 202 and the gate 114c of the third FET 112c, as shown in FIG. 2A. In some examples, a control signal may be provided from the gate control input 202 to the gates 114 of the plurality of FETs 112 to control operation of the switch 200. Being that the common resistor 204 is coupled between the gate control input 202 and the gate 114c of the third FET 112c, the control signal may be center fed symmetrically to the gates 114 of the plurality of FETs 112 via the plurality of gate-to-gate resistors 206. For example, the center feed arrangement may allow the third FET 112c to be turned on/off first and the first and fifth FETs 112a, 112e may be turned on/off at substantially the same time. As such, the switch 200 may be operated with a substantially similar turn on/off response (i.e., switching time, settling time, etc.) for signals received at both the signal input 102 and the signal output 104.

In certain examples, the switch 200 may be configured to operate in an “on state” by turning on each FET of the plurality of FETs 112. In some examples, when turned on, each FET of the plurality of FETs 112 may provide a conductive signal path having a drain-to-source resistance (Rₒₙ). In some examples, the Rₒₙ of each FET may be substantially smaller than the value of the corresponding drain-source resistor (e.g., 208a, 208b, etc.) and the value of the corresponding gate-to-gate resistor (e.g., 206a, 206b, etc.). As such, in the on state of the switch 200, the drain-source resistors 208 and the gate-to-gate resistors 206 may be bypassed to provide a signal path from the signal input 102, through the plurality of FETs 112, to the signal output 104 Likewise, the switch 200 may be configured to operate in an “off state” by turning off the plurality of FETs 112 to disconnect the signal path between the signal input 102 and the signal output 104.

A control signal may be provided from the gate control input 202, through the common resistor 204 and the plurality of gate-to-gate resistors 206 to turn on the plurality of FETs 112. In some examples, to turn on each FET, the gate-to-source voltage of each FET must cross a gate threshold voltage by charging a gate capacitance. In one example, the gate capacitance of each FET includes a gate-to-drain capacitance, a gate-to-source capacitance, and a gate-to-body capacitance. Once the gate capacitance of a FET is charged, the gate-to-source voltage may cross the gate threshold voltage, turning the FET on. Likewise, to turn off each FET of the plurality of FETs 112, the gate-to-source voltage of each FET must be lowered below the gate threshold voltage by discharging the gate capacitance.

When the switch 200 is turned off, each FET of the plurality of FETs 112 may be turned off to disconnect the signal path between the signal input 102 and the signal output 104. In some examples, the drain 116 and/or source 118 of each FET may be AC coupled to the gate 114 via the gate capacitance (i.e., the gate-to-drain capacitance, gate-to-source capacitance, and gate-to-body capacitance). For example, the gate 114a of the first FET 112a may be AC coupled to the drain 116a via the gate capacitance, effectively coupling the gate 114a to the signal input 102 Likewise, the gate 114e of the fifth FET 112e may be AC coupled to the source 118e via the gate capacitance, effectively coupling the gate 114e to the signal output 104. In one example, when the switch 200 is turned off, the impedance seen by an RF signal applied to either the signal input 102 or the signal output 104 may include the plurality of gate-to-gate resistors 206 combined in series. As such, the off resistance (R_{off}) of the switch 200 may correspond, at least in part, to the series combination of the gate-to-gate resistors 206. In some examples, the impedance seen by the RF signal applied to either the signal input 102 or the signal output 104 (i.e., R_{off}) may also include the plurality of drain-source resistors 208 combined in series. In certain examples, the common resistor 204 may also contribute to R_{off}.

When the switch 200 is turned on, each FET of the plurality of FETs 112 may be turned on to provide a signal path from the signal input 102 to the signal output 104. As shown in FIG. 2B, during the on state of the switch 200, an input RF signal having an input voltage Vin may be received at the signal input 102 and an output RF signal having an output voltage Vout may be provided to the signal output 104. In some examples, the difference between the input voltage Vin and the output voltage Vout may correspond to power dissipated in the switch 200 (i.e., insertion loss). For example, as described above, when turned on, each FET may provide a conductive signal path having a drain-to-source resistance (Rₒₙ) and each FET may dissipate an amount of power corresponding to the value of Rₒₙ. In one example, the amount of power dissipated by each FET may be relatively small and, as such, the values of the RF voltages between each FET (i.e., V1a-V1d) may be substantially similar. Being that the plurality of drain-source resistors 208 are coupled across each of the plurality of FETs 112, the same voltages V1a-V1d may appear between each of the drain-source resistors 208. Since the values of V1a-V1d are substantially similar, the voltage differentials across each of the drain-source resistors 208 (e.g., V1a-V1b, V1b-V1c, etc.) may be relatively small resulting in minimal power dissipation associated with the drain-source resistors 208.

As described above, the drain 116 and/or source 118 of each FET 112 may be AC coupled to the gate 114 via the gate capacitance (i.e., the gate-to-drain capacitance, gate-to-source capacitance, and gate-to-body capacitance). For example, the gate 114a of the first FET 112a may be AC coupled to the drain 116a and the source 118a via the gate capacitance and the gate capacitance may function as a voltage divider, resulting in an RF voltage V2a at the gate 114a. In one example, the value of V2a may correspond to a value between Vin and V1a. Likewise, an RF voltage V2b corresponding to a value between V1a and V1b may appear at the gate 114b of the second FET 112b, an RF voltage V2c corresponding to a value between V1b and V1c may appear at the gate 112c of the third FET 112c, and so on. Being that the values of V1a-V1d are substantially similar, the values of V2a-V2e may also be substantially similar and the voltage differentials across each of the gate-to-gate resistors 206 (e.g., V2a-V2b, V2b-V2c, etc.) may be relatively small resulting in minimal power dissipation associated with the gate-to-gate resistors 206.

In some examples, the most significant source of power loss during the on state of the switch 200 may be power dissipation in the common resistor 204. In one example, the gate control input 202 may be configured to present a low impedance path to ground for RF signals (e.g., at the frequency of the input RF signal). For example, a shunt capacitor may be coupled to the gate control input 202 in parallel with circuitry configured to provide the control signal (not shown). The value of the capacitor may be selected such that RF signals at the gates 114 are shunted to ground through the common resistor 204. As such, the voltage differential across the common resistor 204 may be substantially the same as V2c (e.g., V2c-0V) and the common resistor 204 may dissipate an amount of power corresponding to V2c. In some examples, V2c may be substantially similar to the peak RF voltage seen by the switch 200 (e.g., Vin). As such, the value selected for the common resistor 204 may be larger than the values selected for the plurality of gate-to-gate resistors 206 and the plurality of drain-source resistors 208 to minimize power dissipation. In one example, the switching time of the switch 200 may correspond, at least in part, to the value of the common resistor 204, and the value of the common resistor 204 may be selected to minimize power dissipation while maintaining an acceptable switching time. In some examples, by limiting loss to the common resistor 204 (i.e., minimal loss in the plurality of gate-to-gate resistors 206 and the plurality of drain-source resistors 208), the overall insertion loss of the switch 200 may be improved.

In one example, being that the gate-to-gate resistors 206 and the drain-source resistors 208 each contribute to R_{off} in series and dissipate relatively small amounts of power, the values of the gate-to-gate resistors 206 and/or the drain-source resistors 208 may be reduced. An example of resistor parameters for the switch 200 is illustrated in Table 1 below:

TABLE 1

| Resistor | Value | Width | Length |
|---|---|---|---|
| Rds | 10 | 0.7 | 5 |
| Rgg | 7.7 | 0.7 | 4 |
| Rcom | 45 | 3 | 30 |

As shown in Table 1, the gate-to-gate resistors 206 (Rgg) and the drain-source resistors 208 (Rds) may have relatively small values (shown in kΩ). In some examples, reducing the values of the resistors 206, 208 may allow for the use of resistors having smaller dimensions, occupying less area on the die (shown in um). In one example, smaller dimensions may correspond to a resistor having a longer length than width. As described above, the value of the common resistor 204 (Rcom) may be larger than the values of the gate-to-gate resistors 206 (Rgg) and the drain-source resistors 208 (Rds). For example, the value of Rcom may be 4 to 5 times that of Rds and/or Rgg. The common resistor 204 may also have smaller dimensions. In some examples, the common resistor 204 may include multiple resistors coupled in series or parallel. For example, to achieve the resistance value of 45 kΩ as shown, three 135 kΩ resistors may be coupled in parallel. In one example, each of the three 135 kΩ resistors may have a width of 1 um and a length of 10 um to achieve the overall dimensions of 3/30 um as shown. In some examples, by having smaller dimensions, the resistors (i.e., 204, 206, 208) may experience less roll-off at high frequency, improving broadband performance of the switch 200. In certain examples, reducing the values of the drain-source resistors 208 may also help maintain an acceptable switching time of the switch 200.

FIG. 2C illustrates an example layout of a transistor-based signal switch 250. In one example, the switch 250 may be substantially the same as the switch 200 of FIG. 2A, except the switch 250 includes eleven FETs 252a-252k. In one example, the switch 250 includes ten gate-to-gate resistors 256a-256j, eleven drain-source resistors 258a-258k, and a common resistor 254. As shown, the use of small area (reduced width and length) resistors may allow the gate-to-gate resistors 256a-256j to be arranged in a row adjacent to the FETs 252a-252k and inter-resistor routing may be minimized. In some examples, minimizing inter-resistor routing can reduce parasitic capacitances and improve performance the switch 250 (e.g., reduce loss, improve switching time, etc.). In addition, the use of small area resistors may allow for the footprint of the switch layout to be reduced. As shown, the common resistor 254 may be positioned near the center of the FETs 252a-252k to provide the symmetrical center feed arrangement described above. For example, the common resistor 254 is positioned next to the FET 252f such that a control signal provided via the common resistor 254 is fed symmetrically through the gate-to-gate resistors 256a-256j to the FETs 252a-252k.

In certain embodiments, the switch 200 may include a plurality of body-to-body resistors similar to the plurality of gate-to-gate resistors 206. FIG. 2D illustrates a transistor-based signal switch 270 including a plurality of body-to-body resistors 214. In one example, the plurality of body-to-body resistors 214 may be coupled between the body contacts 216 of the plurality of FETs 112. For example, a first body-to-body resistor 214a may be coupled between the body contact 216a of the first FET 112a and the body contact 216b of the second FET 112b and a second body-to-body resistor 214b may be coupled between the body contact 216b of the second FET 112b and the body contact 216c of the third FET 112c. Likewise, a third body-to-body resistor 214c may be coupled between the body contact 216c of the third FET 112c and the body contact 216d of the fourth FET 112d and a fourth body-to-body resistor 214d may be coupled between the body contact 216d of the fourth FET 112d and the body contact 216e of the fifth FET 112e.

In some examples, a common body resistor 212 may be coupled between a body control input 210 and the body contact 216 of one of the plurality of FETs 112. Similar to the common resistor 204, the common body resistor 212 may be coupled between the body control input 210 and the body contact 216 of the FET positioned substantially in the center of the plurality of FETs 112 (e.g., the body contact 216c of the third FET 112c). A control signal may be provided from the body control input 210 to the body contacts 216 of the plurality of FETs 112 to control operation of the switch 270.

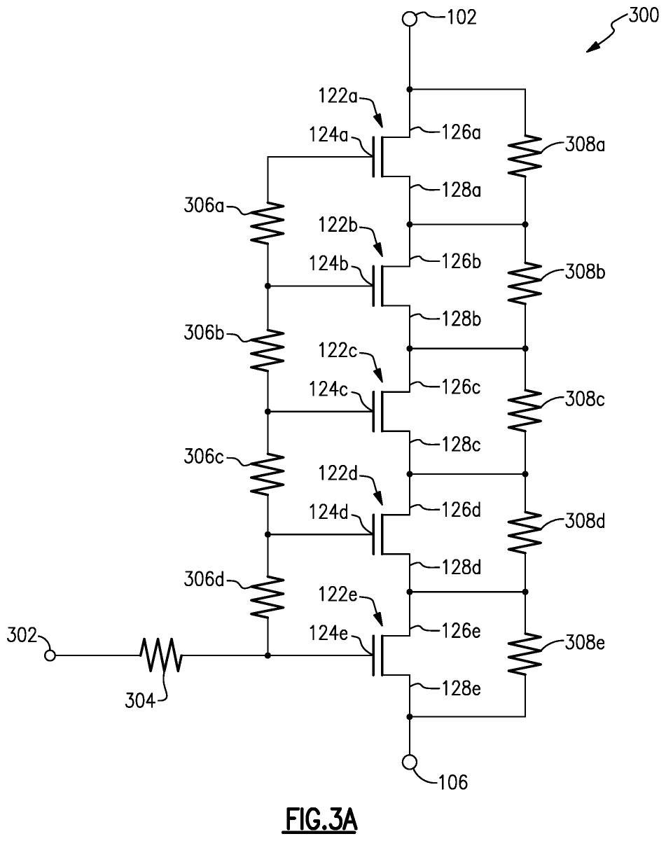

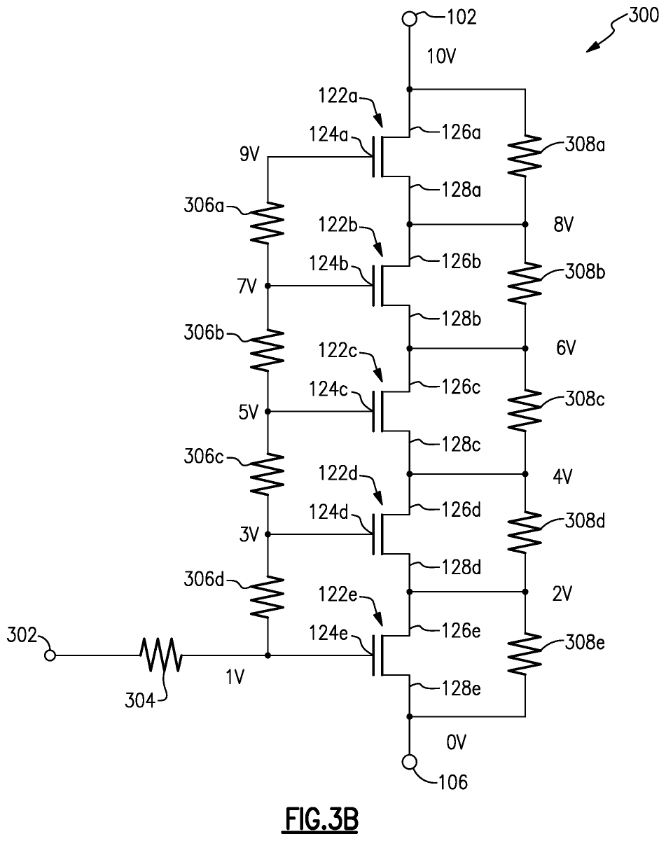

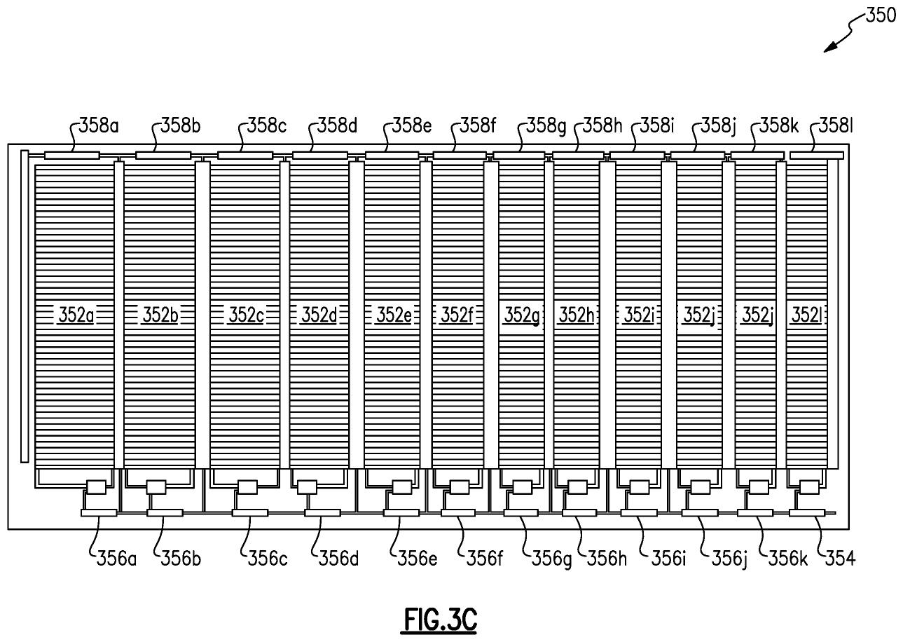

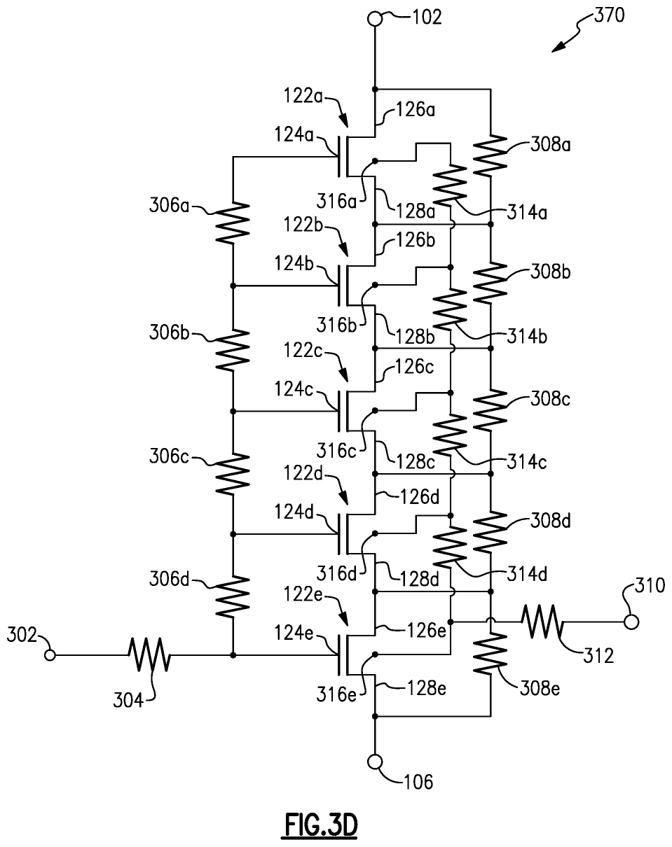

FIG. 3A illustrates one example of a transistor-based signal switch 300. In one example, the switch 300 may be substantially similar to the shunt switch 120 of FIGS. 1B and 1C, except that the switch 300 includes a gate control input 302 and a common resistor 304 coupled between the gate control input 302 and a plurality of gate-to-gate resistors 306. In some examples, the switch 300 may include a plurality of drain-source resistors 308.

In one example, the plurality of FETs 122 of the switch 300 includes a first FET 122a, a second FET 122b, a third FET 122c, a fourth FET 122d, and a fifth FET 122e coupled between the signal input 102 and the reference node 106; however, in various examples, the plurality of FETs 122 may include a different number of FETs. In other examples, the plurality of FETs 122 may be coupled between the signal output 104 and the reference node 106.

As shown in FIG. 3A, a first gate-to-gate resistor 306a may be coupled between the gate 124a of the first FET 122a and the gate 124b of the second FET 122b and a second gate-to-gate resistor 306b may be coupled between the gate 124b of the second FET 122b and the gate 124c of the third FET 122c. Likewise, a third gate-to-gate resistor 306c may be coupled between the gate 124c of the third FET 122c and the gate 124d of the fourth FET 122d and a fourth gate-to-gate resistor 306d may be coupled between the gate 124d of the fourth FET 122d and the gate 124e of the fifth FET 122e.

In some examples, the switch 300 may include the plurality of drain-source resistors 308 coupled in parallel with the plurality of FETs 122. For example, a first drain-source resistor 308a may be coupled in parallel with the first FET 122a, a second drain-source resistor 308b may be coupled in parallel with the second FET 122b, and so on. In one example, each resistor of the plurality of drain-source resistors 308 may have substantially the same value; however, in other examples, at least one of the resistors may have a different value.

As described above, the plurality of FETs 122 may be coupled between the signal input 102 (or the signal output 104) and the reference node 106, and the switch 300 may be configured to receive an RF signal at the signal input 102 (or the signal output 104). As such, the common resistor 304 may be coupled between the gate control input 302 and the gate 124 of the FET positioned at the bottom of the stack (i.e., closest to the reference node 106). For example, the common resistor 304 may be coupled between the gate control input 302 and the gate 124e of the fifth FET 122e, as shown in FIG. 3A. In other examples, the common resistor 304 may be coupled between the gate control input 302 and the gate of a different FET (e.g., gate 124d of the fourth FET 122d). In some examples, a control signal may be fed from the gate control input 302, through the common resistor 304 and the gate-to-gate resistors 306, to the gates 124 of the plurality of FETs 122 to control operation of the switch 300.

In certain examples, the switch 300 may be configured to operate in an “on state” by turning on each FET of the plurality of FETs 122. In some examples, when turned on, each FET may provide a conductive signal path having a drain-to-source resistance (Rₒₙ). In some examples, the Rₒₙ of each FET may be substantially smaller than the value of the corresponding drain-source resistor (e.g., 308a, 308b, etc.) and the value of the corresponding gate-to-gate resistor (e.g., 306a, 306b, etc.). As such, in the on state of the switch 300, the drain-source resistors 308 and the gate-to-gate resistors 306 may be bypassed to provide a signal path from the signal input 102, through the plurality of FETs 122, to the reference node 106 (i.e., ground). Likewise, the switch 300 may be configured to operate in an “off state” by turning off the plurality of shunt FETs 122 to disconnect the signal path between the signal input 102 and the reference node 106.

As described above, a control signal may be provided from the gate control input 302, through the common resistor 304 and the plurality of gate-to-gate resistors 306 to turn on the plurality of FETs 122. In some examples, to turn on each FET, the gate voltage of each FET must cross a gate threshold voltage by charging the gate capacitance. Once the gate capacitance of a FET is charged, the gate voltage may cross the gate threshold voltage, turning the FET on. Likewise, to turn off each FET, the gate voltage of each FET must be lowered below the gate threshold voltage by discharging the gate capacitance.

When the switch 300 is turned on, each FET of the plurality of FETs 122 may be turned on to provide a signal path from the signal input 102 to the reference node 106. As described above, when turned on, the conductive signal path provided by each FET may have a drain-to-source resistance (Rₒₙ) smaller than the values of the gate-to-gate resistors 306 and the drain-source resistors 308. As such, in the on state of the switch 300, the resistors 306, 308 may be bypassed and any power dissipation associated with the resistors 306, 308 may be minimal. In some examples, each FET may dissipate a relatively small amount of power corresponding to the value of Rₒₙ.

In some examples, the gate control input 302 may be configured to present a low impedance path to ground for RF signals (e.g., at the frequency of the input RF signal). For example, a shunt capacitor may be coupled to the gate control input 302 in parallel with circuitry configured to provide the control signal (not shown). The value of the capacitor may be selected to provide a path to ground via the common resistor 304 for RF signals appearing at the gates 124. As such, the common resistor 304 may dissipate an amount of power corresponding to an RF voltage at the gate 124e of the fifth FET 122e. Being that signal input 102 is coupled to the reference node 106 (i.e., ground), the RF voltage at the gate 124e of the fifth FET 122e may be relatively small (0V). As such, power dissipation in the common resistor 304 may be minimal when the switch is turned on.

As described above, when the switch 300 is turned off, each FET of the plurality of FETs 122 may be turned off to disconnect the signal path between the signal input 102 and the reference node 106. In some examples, the drain 126 and/or source 128 of each FET 122 may be AC coupled to the gate 124 via the gate capacitance (i.e., the gate-to-drain capacitance, gate-to-source capacitance, and gate-to-body capacitance). For example, the gate 124a of the first FET 122a may be AC coupled to the drain 126a via the gate capacitance, effectively coupling the gate 124a to the signal input 102. Likewise, the gate 124e of the fifth FET 122e may be AC coupled to the source 128e via the gate capacitance, effectively coupling the gate 124e to the reference node 106. In some examples, when the switch 300 is turned off, the impedance seen by an RF signal applied to the signal input 102 may include the plurality of gate-to-gate resistors 306 combined in series. As such, the off resistance (R_{off}) of the switch 300 may correspond, at least in part, to the series combination of the gate-to-gate resistors 306. In one example, the impedance seen by the RF signal applied to the signal input 102 (i.e., R_{off}) may also include the plurality of drain-source resistors 308 combined in series and the common resistor 304. In some examples, increasing R_{off} may help reduce insertion loss when the switch is turned off; i.e., power loss in the switch 300 when an RF signal is applied to the signal input 102.

In one example, the switch 300 may be configured to distribute an RF voltage corresponding to the RF signal applied at the signal input 102 across the plurality of FETs 122 during the off state. In some examples, the elements of the switch 300 may function as a voltage divider to distribute the RF voltage across the plurality of FETs 122. For example, the gate-to-gate resistors 306, the drain-source resistors 308, and the parasitic capacitances of the plurality of FETs 122 (e.g., parasitic gate capacitance, drain-to-source capacitance, etc.) may each contribute to the distribution of the RF voltage across the plurality of FETs 122. In some examples, each FET of the plurality of FETs 122 may have substantially similar parasitic capacitances. As such, the values of the gate-to-gate resistors 306 and the drain-source resistors 308 may be selected to achieve a desired voltage distribution for the switch 300. In one example, the desired voltage distribution may be a substantially even distribution across each FET of the plurality of FETs 122; however, in other examples a different voltage distribution may be desired. In some examples, the desired voltage distribution may be selected to prevent the plurality of FETs 122 from entering a breakdown region.

FIG. 3B illustrates the switch 300 while turned off. In one example, an RF signal having an RF voltage (e.g. 10V) is applied at the signal input 102 and distributed across the plurality of FETs 122. As shown, substantially similar portions of the RF voltage (e.g., 2V) may be distributed across each FET of the plurality of FETs 122. In one example, based on the voltage distribution of the switch 300, portions of the RF voltage may be present at each gate 124 of the plurality of FETs 122. In some examples, the power dissipated by each of the gate-to-gate resistors 306 may be determined, at least in part, by the voltage differential between the gates 124 of adjacent FETs. For example, the power dissipated by the first gate resistor 306a may correspond to the voltage differential between the gate 124a of the first FET 122a and the gate 124b of the second FET 122b (e.g. 2V), the power dissipated by the second gate resistor 306b may correspond to the voltage differential between the gate 124b of the second FET 122b and the gate 124c of the third FET 122c (e.g. 2V), and so on. In some examples, the power dissipated by each resistor 306 may be substantially the same; however, in other examples, the power dissipated by each resistor may vary. Likewise, the drain-source resistors 308 may be configured to dissipate power corresponding to portions of the RF voltage in a similar manner. In one example, the amount of power dissipated by the common resistor 304 may correspond to the RF voltage at the gate 124e of the fifth FET 122e (e.g., 1V). As such, being that the gate 124e of the fifth FET 122e sees the lowest RF voltage of the plurality of FETs 122, the power dissipated by the common resistor 304 may be relatively small.

As described above, the gate-to-gate resistors 306 may contribute to R_{off} as a series combination and each resistor may only dissipate an amount of power corresponding to a portion of an RF input voltage. Likewise, the drain-to-source resistors 308 may also contribute to R_{off} as a series combination and each resistor 308 may only dissipate an amount of power corresponding to a portion of the RF input voltage. In some examples, being that the resistors dissipate power corresponding to portions of the RF input voltage, the power handling capability of the switch 300 may be improved. In addition, being that the gate-to-gate resistors 306 and the drain-source resistors 308 each contribute to R_{off} as series combinations, the values of the resistors may be reduced. In some examples, reducing the values of the resistors may contribute to maintaining an acceptable switching speed of the switch 300. In certain examples, the switching speed may be dominated by the gate-to-gate resistors 306 and it may be advantageous to use larger values for the drain-source resistors 308 relative to the values of the gate-to-gate resistors 306 to improve R_{off} while maintaining an acceptable switching speed. Likewise, being that the power dissipated by the common resistor 304 is relatively small, the value of the common resistor 304 may have a minimal effect on R_{off}. As such, the value of the common resistor 304 may also be reduced to further improve switching speed.

An example of resistor parameters for the switch 300 is illustrated in Table 2 below:

TABLE 2

| Resistor | Value | Width | Length |
|---|---|---|---|
| Rds | 20 | 0.7 | 9 |
| Rgg | 10 | 0.7 | 4 |
| Rcom | 10 | 0.7 | 5 |

As shown in Table 2, the gate-to-gate resistors 306 (Rgg) and the drain-source resistors 308 (Rds) may have relatively small values (shown in kΩ). In some examples, reducing the values of the resistors may allow for the use of resistors having smaller dimensions, occupying less area on the die (shown in um). In one example, smaller dimensions may correspond to a resistor having a longer length than width. As described above, the common resistor 304 (Rcom) may have a minimal effect on R_{off}, and as such, may have a similar value as the gate-to-gate resistors 306 (Rgg). For example, Rcom may have a value that is substantially the same as Rds and/or Rgg. In some examples, the common resistor 304 may also have smaller dimensions similar to the gate-to-gate resistors 306. In certain examples, the use of small area resistors may allow the resistors (i.e., 304, 306, 308) to experience less roll-off at high frequency, improving broadband performance of the switch 300.

FIG. 3C illustrates an example layout of a transistor-based signal switch 350. In one example, the switch 350 may be substantially the same as the switch 300 of FIGS. 3A, 3B, except the switch 350 includes twelve FETs 352a-352l. In one example, the switch 350 includes eleven gate-to-gate resistors 356a-356k, twelve drain-source resistors 358a-358l, and a common resistor 354. As shown, the use of small area (reduced width and length) resistors may allow the gate-to-gate resistors 356a-356k to be arranged in a row adjacent to the FETs 352a-352l such that inter-resistor routing can be minimized. In some examples, minimizing inter-resistor routing may reduce parasitic capacitances and improve performance of the switch 350 (e.g., reduce loss, improve switching time, etc.). In addition, the use of small area resistors may allow for the footprint of the switch layout to be reduced. As shown, the common resistor 354 may be positioned near the FET at the end of the shunt stack to provide the bottom feed arrangement described above. For example, the common resistor 354 is positioned next to FET 352l such that a control signal provided via the common resistor 354 is fed to the FET 352l and through the gate-to-gate resistors 356a-356k to the FETs 352a-352k.

In some examples, each of the FETs 352a-352l may have dimensions scaled based on the voltage distribution of the switch 350. For example, as described above with respect to the switch 300 of FIG. 3B, the FETs higher in the shunt stack (i.e., closer to the signal input 102) may see larger peak voltages compared to the FETs lower in the shunt stack (i.e., closer to the reference node 106). As such, it may be advantageous to scale the dimensions of the FETs 352a-352l based on each FETs position in the shunt stack. As shown in FIG. 3C, the FETs closest to the signal input 102 (e.g., 352a, 352b) may be larger (e.g., wider) than the FETs closest to the reference node 106 (e.g., 352k, 353l). In some examples, scaling the dimensions of the FETs 352a-352l may contribute to maintaining a consistent broadband voltage distribution across the FETs, improving the linearity of the switch 350.

In certain embodiments, the switch 300 may include a plurality of body-to-body resistors similar to the plurality of gate-to-gate resistors 306. FIG. 3D illustrates a transistor-based signal switch 370 including a plurality of body-to-body resistors 314. In one example, the plurality of body-to-body resistors 314 may be coupled between the body contacts 316 of the plurality of FETs 122. For example, a first body-to-body resistor 314a may be coupled between the body contact 316a of the first FET 122a and the body contact 316b of the second FET 122b and a second body-to-body resistor 314b may be coupled between the body contact 316b of the second FET 122b and the body contact 316c of the third FET 122c. Likewise, a third body-to-body resistor 314c may be coupled between the body contact 316c of the third FET 112c and the body contact 316d of the fourth FET 122d and a fourth body-to-body resistor 314d may be coupled between the body contact 316d of the fourth FET 122d and the body contact 316e of the fifth FET 122e.

In some examples, a common body resistor 312 may be coupled between a body control input 310 and the body contact 316 of one of the plurality of FETs 122. Similar to the common resistor 304, the common body resistor 312 may be coupled between the body control input 310 and the body contact 316 of the FET positioned at the bottom of the stack (i.e., closest to the reference node 106). For example, the common body resistor 312 may be coupled between the body control input 310 and the body contact 316e of the fifth FET 1226e. A control signal may be provided from the body control input 310 to the body contacts 316 of the plurality of FETs 122 to control operation of the switch 370.

Embodiments of the transistor-based signal switches 200, 300 as described herein can be implemented in a variety of different modules and assemblies including, for example, the switches 110, 120 of switch assemblies 100, 125, 150 (FIGS. 1A-1C), a stand-alone RF switch assembly, an RF front-end module, an antenna tuning module, a module combining the switches 200, 300 with a power amplifier, or the like. In certain examples, the transistor-based signal switches 200, 300 may be assembled or arranged to provide an RF switch having a desired number of inputs (e.g., poles) and outputs (e.g., throws).

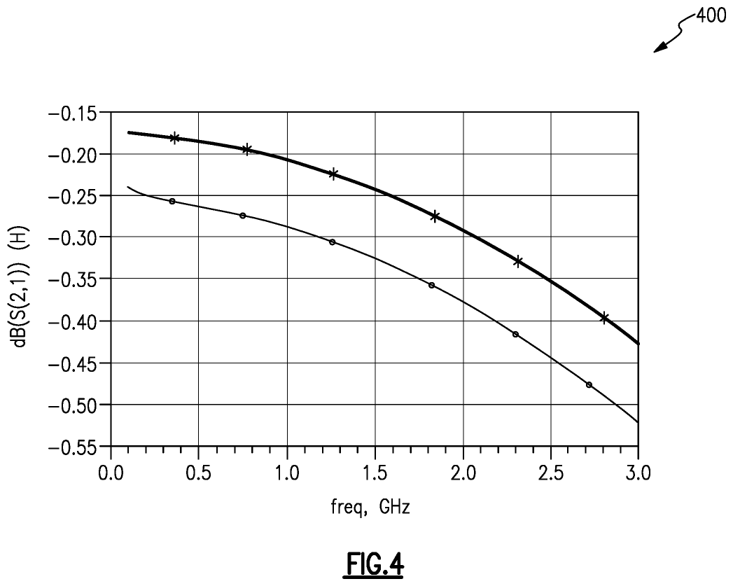

FIG. 4 illustrates simulated performance results of a transistor-based signal switches. In one example, the graph 400 includes performance results for a first single-pole seven-throw (SP7T) switch including an arrangement of transistor-based signal switches (e.g., 110, 120) and a second SP7T switch including an arrangement of transistor-based signal switches having the optimized bias networks described herein (e.g., 200, 300). The graph 400 is coded to indicate the performance is for the first switch (‘o’) and the second switch (‘*’). The graph 400 is a plot showing insertion loss of both switches across frequency (i.e., power loss between output and input). As shown in the graph 400, the second switch including the transistor-based signal switches having the optimized bias networks may experience a 30% reduction in insertion loss compared to the first switch. Being that the reduction in insertion loss is substantially constant across frequency, the utilization of transistor-based signal switches having the optimized bias networks (e.g., 200, 300) may allow the second switch to operate with improved broadband performance relative to the first switch.

In some examples, switch modules described herein may include a substrate and may include various dies and may include packaging, such as, for example, an overmold to provide protection and facilitate easier handling. An overmold may be formed over a substrate and dimensioned to substantially encapsulate the various dies and components thereon. The module may further include connectivity from the transistor-based signal switches 200, 300 to the exterior of the packaging to provide signal interconnections, such as input port connections (e.g., signal input 102), output port connections (e.g., signal output 104), reference port connections (e.g., reference node 106), control input connections (e.g., gate control inputs 202, 302), etc. Certain examples may have multiple connections to accommodate access to various individual components in the module. The various connections may be provided in part by wire bonds or solder bumps, for example, and may include multiple electrical connections where appropriate.

Embodiments of the transistor-based signal switches 200, 300 disclosed herein, optionally packaged into a module, may be advantageously used in a variety of electronic devices. General examples of an electronic device may include a circuit board having numerous modules mounted thereon. The circuit board may have multiple layers and may include circuit elements and interconnections in the layers and/or mounted on the surface of the circuit board. Each of the modules may have a multi-layer substrate within and upon which there may also be various circuit elements and interconnections. Additionally, the modules may further include dies, each of which may have multiple layers and include various circuit elements and interconnections. A transistor-based signal switch in accord with aspects and embodiments disclosed herein may be implemented within, among, or across any of the layers of the various structures, e.g., circuit board, substrates, and dies, as part of an electronic device, such as a cell phone, tablet, laptop computer, smart device, router, cable modem, wireless access point, etc.

As described above, an improved transistor-based signal switch is provided herein. In at least one embodiment, the transistor-based signal switch may have an optimized bias network for reducing insertion loss and improving R_{off} over a broadband performance range. In some examples, the optimized bias network may also increase the power handling capability of the switch and reduce the switch footprint. As such, aspects and embodiments of the RF switch assembly described above may be advantageously used in wireless devices to support, for example, 3G, 4G, LTE, and 5G wireless communications.

What is claimed is:

1. A radio frequency signal switch assembly comprising:
a signal input and a signal output;
a first control input configured to receive a control signal;
a first switch including a first plurality of transistors coupled between the signal input and the signal output, each transistor of the first plurality of transistors having a gate, a drain, and a source;
a first common resistor coupled between the first control input and the gate of one transistor of the first plurality of transistors; and
a first plurality of gate resistors coupled between the gates of the first plurality of transistors, each gate resistor being coupled between the gates of two adjacent transistors.

2. The switch assembly of claim 1 wherein the first common resistor is coupled to the gate of the transistor disposed closest to the center of the first plurality of transistors.

3. The switch assembly of claim 1 wherein an off resistance of the first switch corresponds, at least in part, to a series combination of the first plurality of gate resistors.

4. The switch assembly of claim 1 wherein each transistor of the first plurality of transistors further has a body contact, and wherein the switch further comprises a body control node, a common body resistor coupled between the body control node and the body contact of one transistor of the first plurality of transistors, and a plurality of body resistors coupled between the body contacts of the first plurality of transistors, each body resistor being coupled between the body contacts of two adjacent transistors.

5. The switch assembly of claim 4 wherein the common body resistor is coupled to the body of the transistor disposed closest to the center of the first plurality of transistors.

6. The switch assembly of claim 1 further comprising a reference node and a second control node, the reference node configured to be coupled to a reference voltage.

7. The switch assembly of claim 6 further comprising a second switch including a second plurality of transistors coupled between the reference node and one of the signal input and the signal output, each transistor of the second plurality of transistors having a gate, a drain, and a source.

8. The switch assembly of claim 7 further comprising a second plurality of gate resistors coupled between the gates of the second plurality of transistors, each gate resistor being coupled between the gates of two adjacent transistors.

9. The switch assembly of claim 8 further comprising a second common resistor coupled between the second control node and the gate of the transistor of the second plurality of transistors disposed closest to the reference node.

10. A switch for a radio frequency signal switch assembly comprising:
a first node coupled to one of an input and an output of the switch assembly and a second node coupled to a reference voltage;
a control node;
a plurality of transistors coupled between the first and second nodes, each transistor of the plurality of transistors having a gate, a drain, and a source;
a common resistor coupled between the control node and the gate of one transistor of the plurality of transistors; and
a plurality of gate resistors coupled between the gates of the plurality of transistors, each gate resistor being coupled between the gates of two adjacent transistors.

11. The switch of claim 10 wherein the common resistor is coupled to the gate of the transistor disposed closest to the second node.

12. The switch of claim 10 wherein an off resistance of the switch corresponds, at least in part, to a series combination of the plurality of gate resistors.

13. The switch of claim 10 wherein each transistor of the plurality of transistors further has a body contact, and wherein the switch further comprises a body control node, a common body resistor coupled between the body control node and the body contact of one transistor of the plurality of transistors, and a plurality of body resistors coupled between the body contacts of the plurality of transistors, each body resistor being coupled between the body contacts of two adjacent transistors.

14. The switch of claim 13 wherein the common body resistor is coupled to the body of the transistor disposed closest to the second node.

15. A method of designing a switch for a radio frequency signal switch assembly comprising:
arranging a plurality of transistors between a first node and a second node, each transistor of the plurality of transistors having a gate, a drain, and a source;
selecting a common resistor to be coupled between a control node and the gate of one transistor of the plurality of transistors; and
selecting a plurality of gate resistors to be coupled between the gates of the plurality of transistors, each gate resistor being coupled between the gates of two adjacent transistors.

16. The method of claim 15 wherein the first node is configured to be coupled to an input of the switch assembly and the second node is configured to be coupled to an output of the switch assembly.

17. The method of claim 16 further comprising coupling the common resistor to the gate of the transistor disposed closest to the center of the plurality of transistors.

18. The method of claim 15 wherein the first node is configured to be coupled to one of an input and an output of the switch assembly and the second node is configured to be coupled to a reference voltage.

19. The method of claim 18 further comprising coupling the common resistor to the gate of the transistor disposed closest to the second node.

20. The method of claim 15 wherein selecting the plurality of gate resistors includes selecting the plurality of gate resistors to provide a desired off resistance of the switch, the off resistance of the switch corresponding, at least in part, to a series combination of the plurality of gate resistors.
